(19) United States
(12) Patent Application Publication
(10) Pub. No.: US 2025/0336869 A1
(43) Pub. Date: Oct. 30, 2025

(54) CONDUCTIVE BUMP STRUCTURE

(71) Applicant: SILICONWARE PRECISION INDUSTRIES CO., LTD., Taichung City (TW)

(72) Inventors: Tzu-Chi TSENG, Taichung City (TW); Chih-Sheng LIN, Taichung City (TW); Chih-Yuan SHIH, Taichung City (TW)

(21) Appl. No.: 18/824,580

(22) Filed: Sep. 4, 2024

(30) Foreign Application Priority Data
Apr. 26, 2024 (TW) 113115811

(51) Int. Cl. H01L 23/00

(52) U.S. Cl. CPC H01L 24/13; H01L 24/04; H01L 24/05; H01L 2224/0401; H01L 2224/05005; H01L 2224/05011; H01L 2224/05015; H01L 2224/05017; H01L 2224/05083; H01L 2224/05124; H01L 2224/05187; H01L 2224/05647; H01L 2224/05666; H01L 2224/05684; H01L 2224/13006; H01L 2224/13147; H01L 2924/3512

(57) ABSTRACT

A conductive bump structure is provided, in which a protective layer, an insulating layer, a metal layer, and a metal bump are formed in sequence on a bonding pad of a semiconductor substrate, wherein a thickness and a width of the second area of the insulating layer that is not covered by the metal bump are greater than a thickness and a width of the first area that is covered by the metal bump, respectively. Accordingly, the stress on the semiconductor substrate can be reduced.

### CROSS-REFERENCE TO RELATED APPLICATIONS

The present application is based upon and claims the right of priority to TW Patent application Ser. No. 113115811, filed Apr. 26, 2024, the disclosure of which is hereby incorporated by reference herein in its entirety for all purposes.

### BACKGROUND

### 1. Technical Field

The present disclosure relates to a conductive bump structure, and more particularly, to a conductive bump structure formed on a semiconductor substrate.

### 2. Description of Related Art

Compared with wire bond technology, the flip chip package is characterized in that the electrical connection between the semiconductor chip and the packaging substrate is made by metal bumps instead of usual gold wires. Using metal bumps as electrical connection components has the advantages of shortening the electrical conduction paths, improving performance, providing heat dissipation paths, and reducing the size of the package, etc. Therefore, it has become a trend in packaging.

However, when the semiconductor chip is thermally compressed onto a packaging substrate through metal bumps in a flip-chip manner, the packaging substrate often generates a peeling force that pulls down the metal bumps due to the thermal stress, causing the dielectric layer and/or the metal layer inside the semiconductor chip to crack and be damaged, seriously affecting the reliability of the package.

Therefore, how to overcome the above-mentioned problems of conventional techniques has become an urgent issue to be solved.

### SUMMARY

In view of the aforementioned shortcomings of the prior art, the present disclosure provides a conductive bump structure, which comprises: a protective layer formed on a semiconductor substrate having a bonding pad and formed with an opening at a location corresponding to the bonding pad to expose the bonding pad; an insulating layer formed on the protective layer and located correspondingly at a periphery of the opening, the insulating layer defined with a first area close to the opening and a second area away from the opening, wherein the first area has a first thickness and a first width, the second area has a second thickness and second width, and the second thickness is larger than the first thickness, the second width is larger than the first width; and a metal bump formed on the bonding pad and the insulating layer and corresponding to the location of the opening, wherein the metal bump covers the bonding pad and the first area of the insulating, but is free from covering the second area of the insulating layer.

The aforementioned conductive bump structure further comprises a metal layer formed between the metal bump and the bonding pad.

In the aforementioned conductive bump structure, the metal layer covers the bonding pad, parts of the protective layer and the first area of the insulating layer but is free from covering the second area of the insulating layer.

In the aforementioned conductive bump structure, the metal layer is an Under Bump Metallurgy (UBM).

In the aforementioned conductive bump structure, the protective layer is a passivation layer.

In the aforementioned conductive bump structure, the insulating layer is a Polyimide layer.

In the aforementioned conductive bump structure, the insulating layer is a closed loop structure.

In the aforementioned conductive bump structure, the insulating layer is a loop structure with an open slot.

In the aforementioned conductive bump structure, the second thickness is two times the first thickness at least.

In the aforementioned conductive bump structure, the second width is two times the first width at least.

It can be seen from above, the conductive bump structure of the present disclosure mainly forms a protective layer, an insulating layer, a metal layer, and a metal bump on the bonding pad of the semiconductor substrate in sequence, wherein a thickness and a width of the second area of the insulating layer that is not covered by the metal bump are larger than a thickness and a width of the first area of the insulating layer that is covered by the metal bump, respectively. Accordingly, the stress experienced by the semiconductor substrate can be lowered, thereby preventing the internal crack problem of the semiconductor substrate caused during the thermal process.

### BRIEF DESCRIPTION OF THE DRAWINGS

FIG. 1 is a schematic cross-sectional view of a conductive bump structure according to the present disclosure.

FIG. 2 is a schematic planar partial view of a conductive bump structure according to the present disclosure.

FIG. 3 is a schematic planar partial view of another embodiment of the conductive bump structure according to the present disclosure.

### DETAILED DESCRIPTION

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “a,” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

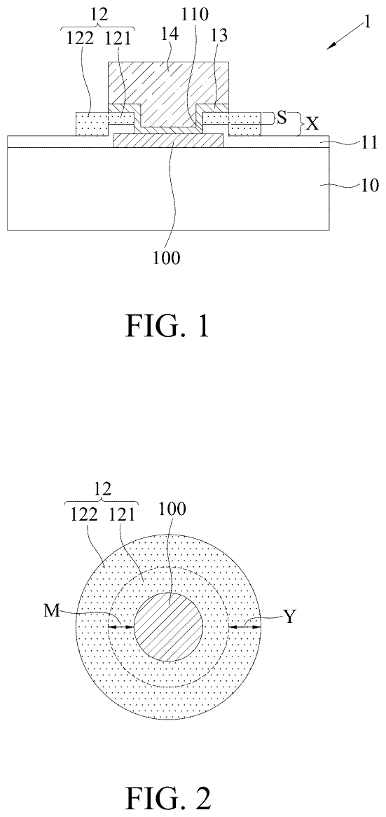

Please refer to FIG. 1 and FIG. 2, which are a schematic cross-sectional view and a schematic planar partial view of a conductive bump structure according to the present disclosure.

First, a semiconductor substrate 10 having a plurality of bonding pads 100 is provided. Only a single bonding pad 100 is shown in the figure as structures on each of the bonding pads 100 are approximately the same.

In one embodiment, the semiconductor substrate 10 is a wafer or a chip, while in another embodiment, the semiconductor substrate 10 may also be a silicon substrate or a glass substrate. A protective layer 11 is formed to cover the semiconductor substrate 10 and has a plurality of openings 110, such that each bonding pad 100 is exposed correspondingly from each opening 110. In addition, an material forming the bonding pad 100 may be aluminum, and a material forming the protective layer 11 may be silicon nitride (SiN) or an oxide of silicon (SiOX) to serve as a passivation layer.

Further, an insulating layer 12 is formed on the protective layer 11 and located correspondingly at a periphery of the opening 110 to cover the protective layer 11 around the opening 110. The insulating layer 12 is defined with a first area 121 that is close to the opening 110 and a second area 122 that is away from the opening 110. In one embodiment, the insulating layer 12 is, for example, a polyimide layer, which is provided on the protective layer 11 by means of a spin coating method, and then undergoes process such as curing, exposure, development and the like to be formed into a closed loop structure located correspondingly at a periphery of the opening 110 and to expose the bonding pad 100.

Then, a metal layer 13 is formed on the bonding pad 100 corresponding to the opening 110, the protective layer 11 and the insulating layer 12 around the opening 110, wherein the metal layer 13 covers the bonding pad 100, part of the protective layer 11, and the first area 121 but not the second area 122 of the insulating layer 12. In one embodiment, the metal layer 13 is an Under Bump Metallurgy (UBM) structure, a material of which may be titanium/copper (Ti/Cu) or titanium/tungsten/copper (Ti/W/Cu).

After that, a metal bump 14 is formed on the metal layer 13 to constitute a conductive bump structure 1. The material of the metal bump 14 is metal copper, for example.

In one embodiment, the first area 121 of the insulating layer 12 that is covered by the metal bump 14 (or the metal layer 13) has a first thickness S and a first width M, the second area 122 of the insulating layer 12 that is not covered by the metal bump 14 (or the metal layer 13) has a second thickness X and a second width Y, wherein the second thickness X is larger than the first thickness S, the second width Y is larger than the first width M. For instance, the second thickness X is two times the first thickness S at least, the second width Y is two times the first width M at least. By the aforementioned design of the insulating layer 12, the stress suffered by the semiconductor substrate 10 can be reduced, and the crack problem of the dielectric layer and/or the metal layer within the semiconductor substrate 10 caused during the thermal process can be avoided.

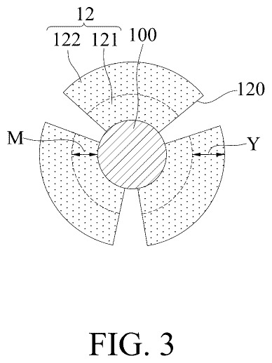

Please refer to FIG. 3, which is a schematic planar partial view of another embodiment of the conductive bump structure according to the present disclosure.

This embodiment is substantially the same as the previous embodiment. The main difference is that the insulating layer 12 is formed with a plurality of open slots 120 connecting the first area 121 and the second area 122 to form a loop structure with open slots.

To sum up, the conductive bump structure of the present disclosure mainly forms a protective layer 11, an insulating layer 12, a metal layer 13, and a metal bump 14 on the bonding pad 100 of the semiconductor substrate 10 in sequence, wherein the thickness and the width of the second area 122 of the insulating layer 12 that is not covered by the metal bump 14 are larger than the thickness and the width of the first area 121 that is covered by the metal bump 14, respectively. Accordingly, the stress suffered by the semiconductor substrate 10 can be reduced, thereby preventing the crack problem within the semiconductor substrate 10 during the thermal process.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. A conductive bump structure formed on a bonding pad of a semiconductor substrate, comprising:
a protective layer formed on the semiconductor substrate and formed with an opening at a location corresponding to the bonding pad to expose the bonding pad;
an insulating layer formed on the protective layer and located correspondingly at a periphery of the opening, the insulating layer defined with a first area close to the opening and a second area away from the opening, wherein the first area has a first thickness and a first width, the second area has a second thickness and second width, and the second thickness is larger than the first thickness, and the second width is larger than the first width; and
a metal bump formed on the bonding pad and the insulating layer and corresponding to the location of the opening, wherein the metal bump covers the bonding pad and the first area of the insulating layer but is free from covering the second area of the insulating layer.

2. The conductive bump structure of claim 1 further comprising a metal layer formed between the metal bump and the bonding pad.

3. The conductive bump structure of claim 2, wherein the metal layer covers the bonding pad, parts of the protective layer and the first area of the insulating layer but is free from covering the second area of the insulating layer.

4. The conductive bump structure of claim 2, wherein the metal layer is an Under Bump Metallurgy (UBM).

5. The conductive bump structure of claim 1, wherein the protective layer is a passivation layer.

6. The conductive bump structure of claim 1, wherein the insulating layer is a polyimide layer.

7. The conductive bump structure of claim 1, wherein the insulating layer is a closed loop structure.

8. The conductive bump structure of claim 1, wherein the insulating layer is a loop structure with an open slot.

9. The conductive bump structure of claim 1, wherein the second thickness is two times the first thickness at least.

10. The conductive bump structure of claim 1, wherein the second width is two times the first width at least.
